(19) United States
(12) Patent Application Publication
(10) Pub. No.: US 2026/0360589 A1
(43) Pub. Date: Nov. 12, 2026

(54) AIR GAP MONITORING SYSTEM, ASSOCIATED METHOD, AND CABLE THEREFOR

(71) Applicant: VIBROSYSTM INC., Longueuil (CA)

(72) Inventors: Mathieu CLOUTIER, Longueuil (CA); Marius CLOUTIER, Longueuil (CA); Sylvain CHAREST, Longueuil (CA); André BRUNELLE, Longueuil (CA); Frédérick CREVIER, Longueuil (CA)

(21) Appl. No.: 19/671,618

(22) Filed: May 8, 2026

Related U.S. Application Data
(60) Provisional application No. 63/803,997, filed on May 12, 2025.

(51) Int. Cl. H01B 11/20; G01B 7/14; G01D 5/24; G01R 31/34; H01B 11/18; H01R 24/22; H01R 24/30; H01R 24/56

(52) U.S. Cl. CPC H01B 11/206; G01B 7/14; G01D 5/24; G01R 31/343; H01B 11/1869; H01R 24/22; H01R 24/30; H01R 24/56

(57) ABSTRACT

The air gap monitoring system can have air gap monitoring system comprising: electronic hardware including a high frequency signal generator having a first output, a second output and a return; a capacitive sensor having a first sensor conductor, a second sensor conductor and a third sensor conductor, having a sensing body secured to an internal surface of a stator of a rotary electric machine and facing a rotor of the rotary electric machine; and a cable connected between the electronic hardware and the capacitive sensor, the cable having a first cable conductor establishing a first electrical connection between the first output and the first sensor conductors, a second cable conductor establishing a second electrical connection between the second output and the second sensor conductor, a third cable conductor establishing a third electrical connection between the return and the third sensor conductor, and a fourth cable conductor connected to a ground reference, the first electrical connection, second electrical connection, third electrical connection and fourth electrical connection being electrically insulated from one another.

### FIELD

Embodiments described herein relate to monitoring systems for rotary electrical machines, and more particularly to air gap monitoring systems using capacitive sensors.

### BACKGROUND

Large, e.g., MW-range, rotary electric machines, such as electrical hydro-generators used for producing electricity, or electrical mills in the mining industry, can be considered “critical” in the sense that eventual downtime can be highly undesirable and associated to significant costs and/or other severe inconveniences. The management of such critical assets is typically associated with certain considerations such as a motivation to avoid failures, limit downtime, and protection against physical intrusions and digital piracy.

Capacitive sensors, sometimes referred to as dielectric sensors or simply as “sensors” when the context is obvious, use capacitance to measure the dielectric permittivity of a surrounding medium. An oscillating electrical field can be generated between conductive elements of a sensing body, and changes in dielectric constant of surrounding media can be detected by changes in the operating frequency. Capacitive sensors are used in a wide variety of applications, including clearance (e.g., air gap) monitoring in rotating machines. In practice, capacitive sensors commonly in use today have multiple superimposed insulated and semi conductive layers.

In some applications, the available space to position the sensing body of the capacitive sensor is limited. In some electric rotating machines, for instance, it can be desired to monitor the space, commonly referred to as an “air gap”, between the stator and the rotor. Accordingly, many electric rotating machines operating nowadays have their stator equipped with one or more capacitive sensors. An example of a large rotary electric machine 10, more specifically a salient pole electric machine, is shown at FIG. 1. Capacitive sensors 12 are affixed to an internal surface 14 of the stator facing the rotor 16 and constantly monitor the “air gap”, a spacing between the rotor 16 and stator 14, while the machine is operating.

In such applications, the radial spacing between the rotor 16 and the stator 14 can be limited, and it can be desired to use a capacitive sensor having a plate-like, flat, thin, sensing body to fit into the limited space. Such capacitive sensors may have a circular or rectangular shape and can be planar or slightly curved. U.S. Pat. No. 11,125,795 presents more detail about example embodiments of capacitive sensors. While other types of air gap sensors than capacitive sensors may theoretically seem possible, practical considerations have led the industry to rely solely on capacitive sensors for air gap monitoring over the last few decades.

Such capacitive sensors 12 are inherently passive and are driven and monitored by electronic hardware 20 which also forms part of the air gap monitoring system 26. In such applications, practical considerations, including the limited available space between the rotor 16 and stator 14 but also the harsh local environment of strong electromagnetic fields during operation of the large rotary electric machines 10, have led to positioning this electronic hardware 20 remotely (e.g., at a distance 24) from the rotary electric machine 10 and connecting it to the sensor 12 by a cable 22.

The signal from many capacitive sensors 12 is very subtle, such as in the picofarad (pF) range, and many orders of magnitude lower than the effects the strong local electromagnetic fields stemming from the operation of the large rotary electrical machine may generate in the vicinity of the capacitive sensor's position. Yet, harnessing this signal was found possible using namely a high frequency signal generator (integrated to the electronic hardware 20), as described namely in U.S. Pat. No. 4,675,670, and has become the standard for air gap monitoring over the last decades.

While existing air gap monitoring systems were found very useful and have been appreciated by large rotary electric machine plant operators as a crucial tool for machine monitoring, there remained room for improvement.

Indeed, in some applications, the electronic hardware 20 can include an oscillator (sometimes referred to as the high frequency generator) and other acquisition equipment such as a signal conditioner, signal processing equipment, and/or linearization electronics, which need to be positioned remotely from the rotating machine for reasons such as to protect the electronic hardware 20 from the harsh environment of the machine 10 and/or to facilitate maintenance or replacement of the electronic hardware. This electronic hardware 20 can be connected to the capacitive sensor(s) 12 using a cable 22. However, the ability to extract a signal of a suitable quality from the capacitive sensor 12 can decrease non-linearly, and in some cases exponentially, with the length of the cable 22.

The distance between the electronic hardware 20 and the rotating machine 10 can be referred to as the remoteness distance, or removal distance 24. It can be desired to increase the remoteness distance 24, but the inconvenience of electromagnetic effects stemming from increasing the length of the cable 22 can impose practical limits. Accordingly, in some cases, a compromise may be reached between the desire to increase the remoteness distance 24 and the need to limit the length of the cable 22, whereas in other embodiments, this compromise may be more difficult, or unfeasible, to achieve. Indeed, in many embodiments, it was not found feasible to use cables having more than 5 or 10 meters in length, for instance.

### SUMMARY

It was found that noise issues affecting signal quality could be alleviated using a quadri-axial cable structure with four concentric electrical conductors separated by electrical insulators to connect the rotating machine 10 to electronic hardware 20. More specifically, inner ones of the electrical conductors can be connected between outputs of the high frequency signal generator of the electronics hardware and conductive layers of the capacitive sensor, an intermediary one of the electrical conductors can be connected between a background of the sensor and a ground of the electronics hardware, and an outer one of the electrical conductors can connect the stator to one or more ground (e.g., ground reference)independently of the intermediary electrical conductor connection.

In accordance with one aspect, there is provided an air gap monitoring system comprising: electronic hardware including a high frequency signal generator having a first output, a second output and a return; a capacitive sensor having a first sensor conductor, a second sensor conductor and a third sensor conductor, having a sensing body secured to an internal surface of a stator of a rotary electric machine and facing a rotor of the rotary electric machine; a cable connected between the electronic hardware and the capacitive sensor, the cable having a first cable conductor establishing a first electrical connection between the first output and the first sensor conductors, a second cable conductor establishing a second electrical connection between the second output and the second sensor conductor, a third cable conductor establishing a third electrical connection between the return and the third sensor conductor, and a fourth cable conductor connected to a ground reference, the first electrical connection, second electrical connection, third electrical connection and fourth electrical connection being electrically insulated from one another.

In accordance with another aspect, there is provided: a method of monitoring an air gap of a rotary electric machine having a stator and a rotor using a capacitive sensor, the capacitive sensor having a background secured to an internal surface of the stator, a sensing surface facing the rotor, and a mask between the internal surface and the background, the method comprising, during operation of the rotary electric machine: communicating a first high frequency signal to the sensing surface via a first electrical conductor of a cable; communicating a second high frequency signal to the mask via a second electrical conductor of the cable; communicating a return signal from the background via a third electrical conductor of the cable; establishing a ground reference of the rotary electric machine in a fourth electrical conductor of the cable; and electrically insulating the first, second, third and fourth electrical conductors from one another.

In accordance with another aspect, there is provided: a cable comprising a length extending between two opposite ends, first conductor extending along the length and externally connectable at the opposite ends, a first insulator surrounding the first conductor, a second conductor surrounding the first insulator and externally connectable at the opposite ends, a second insulator surrounding the second conductor, a third conductor surrounding the second insulator and externally connectable at the opposite ends, a third insulator surrounding the third conductor, and a fourth conductor surrounding the third insulator.

Many further features and combinations thereof concerning the present improvements will appear to those skilled in the art following a reading of the instant disclosure.

### DESCRIPTION OF THE FIGURES

In the figures,

FIG. 1 shows an example of a capacitive sensor mounted on an inner face of a stator of a rotary electric machine, with the electronic hardware being located remotely from the electric machine and connected to the capacitive sensor via a cable, in accordance with the prior art;

FIG. 2 schematically shows a first example air gap monitoring system, with FIG. 2A showing a portion of FIG. 2, enlarged;

FIG. 3 presents an example of a cable which can be used in the context of the air gap monitoring system of FIG. 2;

FIG. 4 presents an example of a sensor and of a cable which can be used in the context of the air gap monitoring system of FIG. 2;

FIG. 5 presents a second example air gap monitoring system;

FIG. 6 presents an example of a cable which can be used in the context of the air gap monitoring system of FIG. 5;

FIG. 7 shows a component which can be used as a conductor in a cable;

FIGS. 8A and 8B are oblique and cross-sectional elevation views, respectively, showing a connection between a cable and electronic hardware; and

FIGS. 9A and 9B are side elevation and cross-sectional views, respectively, showing a connection between a cable and a sensor.

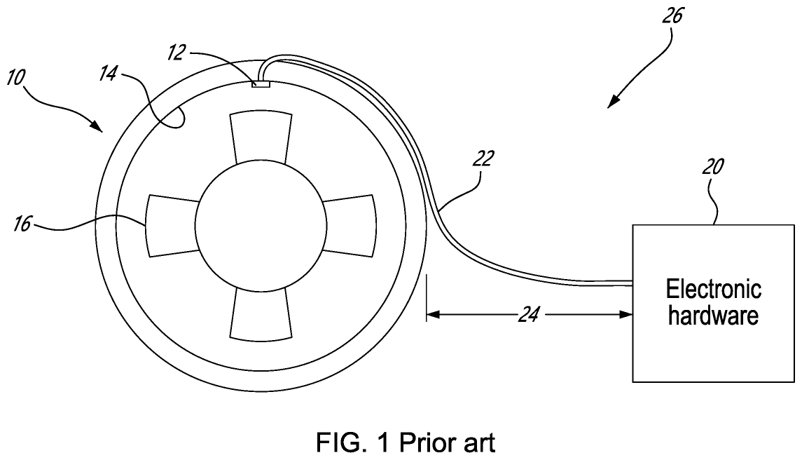

### DETAILED DESCRIPTION

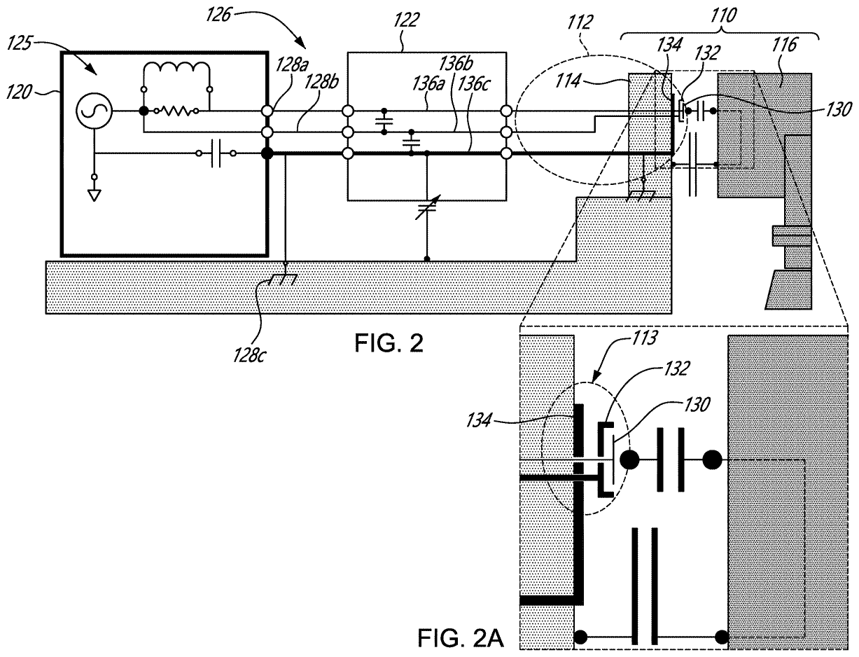

FIG. 2 presents a first example embodiment of an air gap monitoring system 126 coupled to a rotary electric machine 110. The air gap monitoring system 126 includes electronic hardware 120 located remotely from the rotary electric machine 110, a capacitive sensor 112 secured to an inner surface of a stator 114 of the rotary electric machine 110, facing the rotor 116, and a cable 122 connecting the electronic hardware 120 to the capacitive sensor 112.

More specifically, in this example, the electronic hardware 120 includes a signal generator which can be operable to provide two outputs 128a, 128b of a high frequency, constant amplitude signal. The frequency can be above 100 kHz, such as in the range of 400 to 500 kHz, for example. The sensor 112 can have a sensing body 113 having plurality of parallel conductive plates separated by electrical insulation, including a sensing surface 130 (or first conductor), a mask 132 (or second conductor), and a background 134 (or third conductor). The cable 122 can establish three electrical connections 136a, 136b, 136c. A first electrical connection 136a, is established between a first output 128a of the signal generator 125 and the sensing surface 130. A second electrical connection 136b is established between the second output 128b of the signal generator 125 and the mask 132 (embodied here as a guard ring). A third electrical connection 136c is established between the background 134 of the sensor 112, a ground 128c of the electronic hardware, such as a ground of the signal generator 125, and optionally further ground references. The background 134 of the sensor 112 can be connected to a ground of the rotary electric machine.

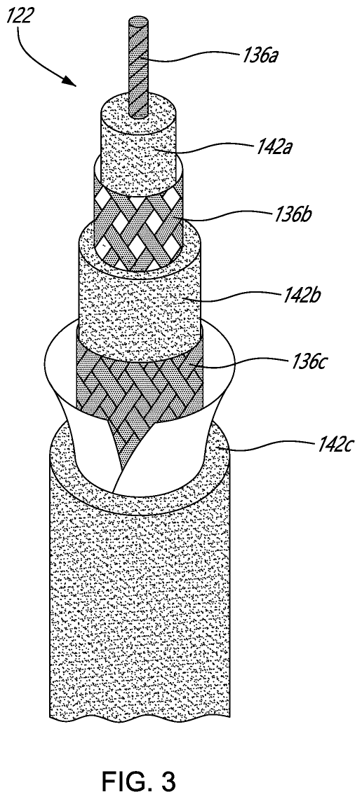

The cable 122 can be embodied as a triaxial cable, an example of which is presented in FIG. 3. The tri-axial cable has three conductors arranged in a concentric fashion relative to one another, and each separated by a layer of electrical insulation (an insulator). A central, first conductor 136a can be used to establish the first connection, an intermediary, second conductor 136b can be used to establish the second connection, and an outer, third conductor 136c can be used to establish the third connection, for example. A first insulator 142a can insulate the first conductor 136a from the second conductor 136b, a second insulator 142b can insulate the second conductor 136b from the third conductor 136c, and a third insulator 142c can surround the third conductor 136c and insulate it from its surroundings.

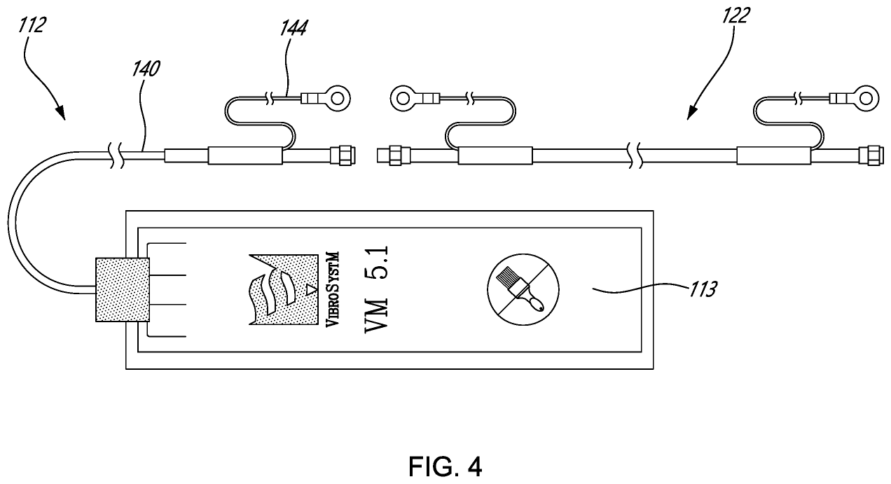

FIG. 4 presents an example of how the cable 122 and sensor 112 can be embodied, in accordance with one potential embodiment. In this example, the sensor 112 has a triaxial cable segment 140 integrally connected to the capacitive sensing body 113. The triaxial cable segment 140 bears a typical coaxial connector which can be used to connect to the first and second conductors 136a, 136b of the cable 122, for example, and a separate connector 144 can be used to connect to the third conductor 136c of the cable 122. The sensing body 113 can be embodied relatively thin and planar, as a laminar structure composed of an alternating superposition of electrically conductive layers and electrically insulating layers. The electrically conductive layers, or conductors, can be made of conductive or semi-conductive materials. The construction of the cable 122 can be similar to the construction of the triaxial cable segment 140, namely to facilitate connectivity, for example. Optionally, additional wires (e.g., wires terminated by separate connectors as shown) can be used to connect the third conductor 136c to one or two ground references.

Returning to FIG. 2, in such an embodiment, capacitances exist within the cable 122, namely between the third conductor 136c and the second conductor 136b, and between the second conductor 136b and the first conductor 136a. These capacitances can have fixed values which depend on the particularities of the construction of the cable, and can thus be factored out, e.g., via calibration. It was found, however, that a parasitic capacitance can exist between the third conductor 136a, which is an outer conductor in this embodiment, and the environment, and that this parasitic capacitance can vary depending on the details of the embodiment and represent a source of noise. Noise can namely stem from crosstalk between adjacent cables, such as between an additional cable disposed adjacent cable 122, for instance. One or more such sources of noise can be difficult to filter out from the subtle signal originating from the sensing surface 130. A consequence of the difficulty of filtering out this noise can be that it may not be feasible to extend the length of the cable 122 past a certain point, and the effect of such sources of noise can be exponentially related to the length of the cable 122.

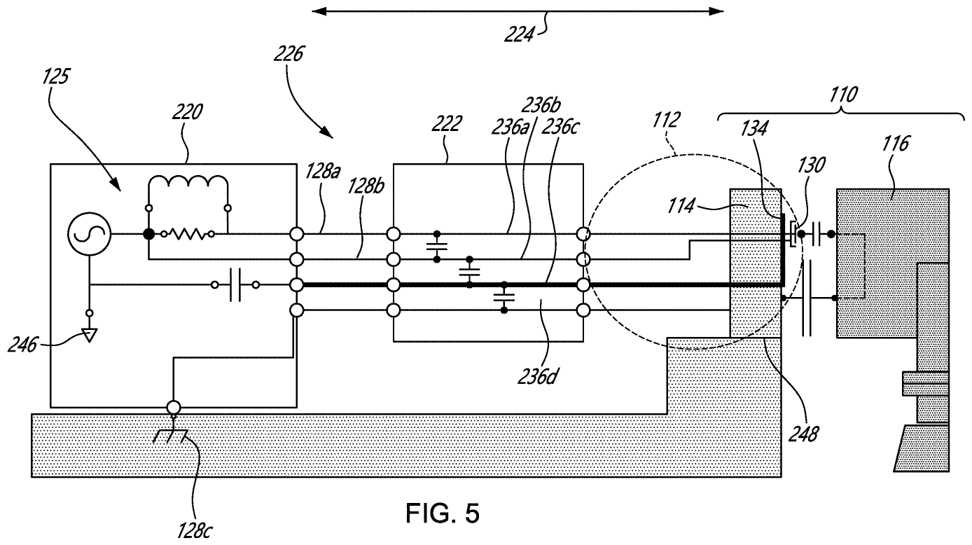

FIG. 5 presents another embodiment of an air gap monitoring system 226 coupled to a rotary electric machine 110. This example has similarities to the example presented in FIG. 2 but also bears some differences. Namely, in this example, four electrical connections 236a, 236b, 236c, 236d are established by the cable 222 as opposed to three. The two first electrical connections 236a, 236b can be comparable in the embodiment of FIG. 5 and in the embodiment of FIG. 2. The third connection 236c can still be used as a return connection to the electronic hardware, but bear some differences. Namely, in the example presented in FIG. 5, the third connection 236c can be established between the background 134 of the sensor 112 and the electronic ground reference of the electronics hardware 220, such as the electronic ground reference 246 of the signal generator 125. The third connection 236 c, and the electronic ground reference 246 can be electrically insulated from the housing ground reference of the electronic hardware (machine ground 128c).

A fourth electrical connection 236d can be established between one or more machine ground references 248 at the stator (machine ground) and one or more ground references at the electronic hardware 220 (e.g., mechanical structure ground 128c). Accordingly, the fourth electrical connection 236d can provide a ground reference which is independent from the return connection 236c to the electronic hardware 220. In this context, the capacitive value between the fourth electrical connection 236d and the third electrical connection 236c can be constant and independent from the particularities of the premises associated to the embodiment. This configuration can be seen to provide electrical insulation between the ground of the electronics 246 and the “machine ground” 138c references of the rotary electrical machine 110 and/or of the housing of the electronic hardware 220.

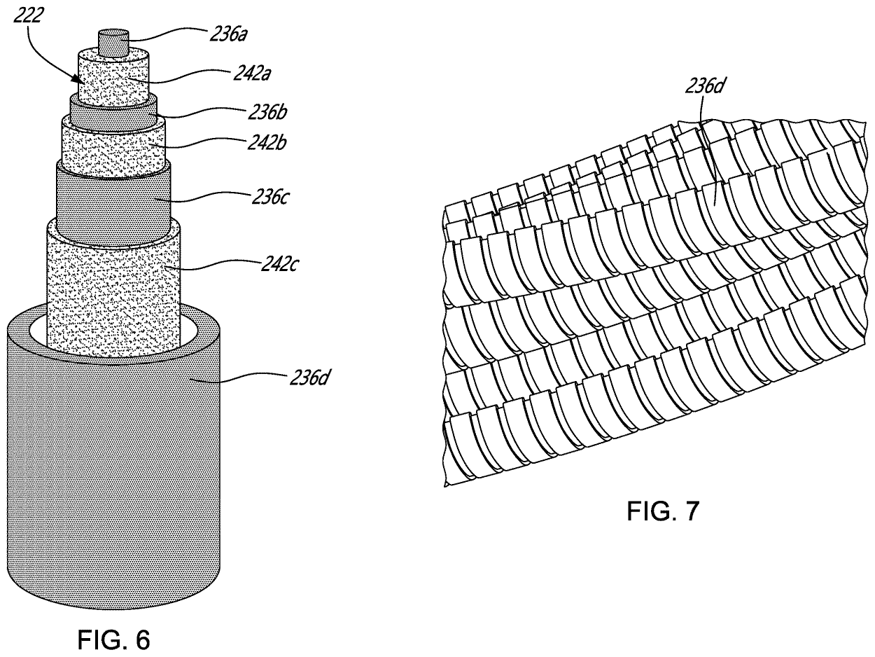

FIG. 6 presents an example embodiment of a cable 222 which can be used in an embodiment such as schematized in FIG. 5. In this example, the cable 222 can be embodied as a quadri-axial cable having four conductors 236a, 236b, 236c, 236d arranged in a concentric arrangement relative one another, each separated from the other by an insulator 242a, 242b, 242c formed of one or more layers of electrically insulating material. In an embodiment, a central conductor 236a can be used to establish the first connection, a second conductor 236b surrounding the central conductor 236a can be used to establish the second connection, a third conductor 236c surrounding the second conductor 236b can be used to establish the third connection, and a fourth conductor 236d surrounding the third conductor 236c can be used to establish the fourth connection. In some embodiments, fourth conductor 236d can be left exposed as the outer layer of the cable 222, and the outer layer of the cable can thus be an electrical conductor rather than an electrical insulator by comparison with an embodiment such as shown in FIG. 4. In some embodiments, the outer layer of the cable 222, forming the fourth conductor 236d, can be formed of a metallic “interlock” type flexible conduit, an example of which is presented in FIG. 7. The metallic interlock outer layer can be formed of stainless steel, for example. The first three conductors 236a, 236b, 236c and insulators 242a, 242b, 242c can be embodied as a tri-axial cable, for example. The metallic interlock outer layer can have a diameter adapted to the specifics of the first three conductor and insulator layers. In some embodiments, the metallic interlock outer layer can have an inner diameter of 8 mm, and an outer diameter of 10.5 mm, for instance.

The cable 222 can be provided with connectors at both ends to facilitate the establishment of the electrical connections between the cable and other components, such as the electronic hardware 220, the sensor 112, (e.g., triaxial cable segment 140), grounds, or other components. Indeed, in the context of an electrical connection scheme such as shown in FIG. 5, sources of noise which were dependent on cable length in an embodiment such as shown in FIG. 2 may be eliminated, facilitating the task of increasing the length of the cable 222 and accordingly increasing the remoteness distance 224. In some embodiments, to increase remoteness distance 224, it may be deemed convenient to simply connect, in series, a number of different cables 222 having shorter, e.g., standard, lengths. In some embodiments, this standard length may be 5m or 10 m, for instance, and some facilities may benefit from connecting two, or more of such standard length cables 222, in series between the electronics hardware 220 and the sensor 112, achieving overall lengths of over 15 m, over 20 m, or even over 25 m.

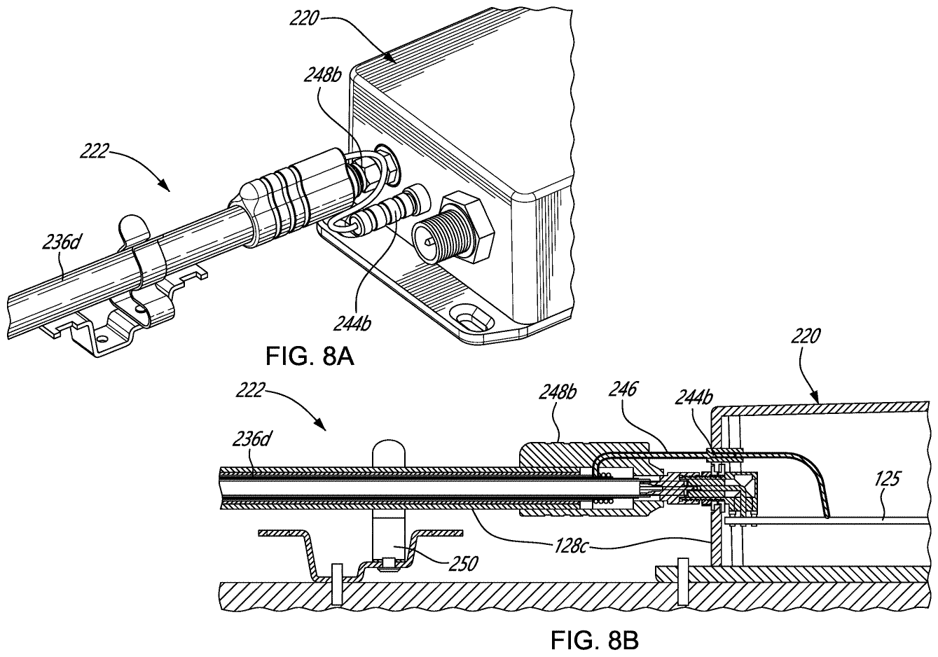

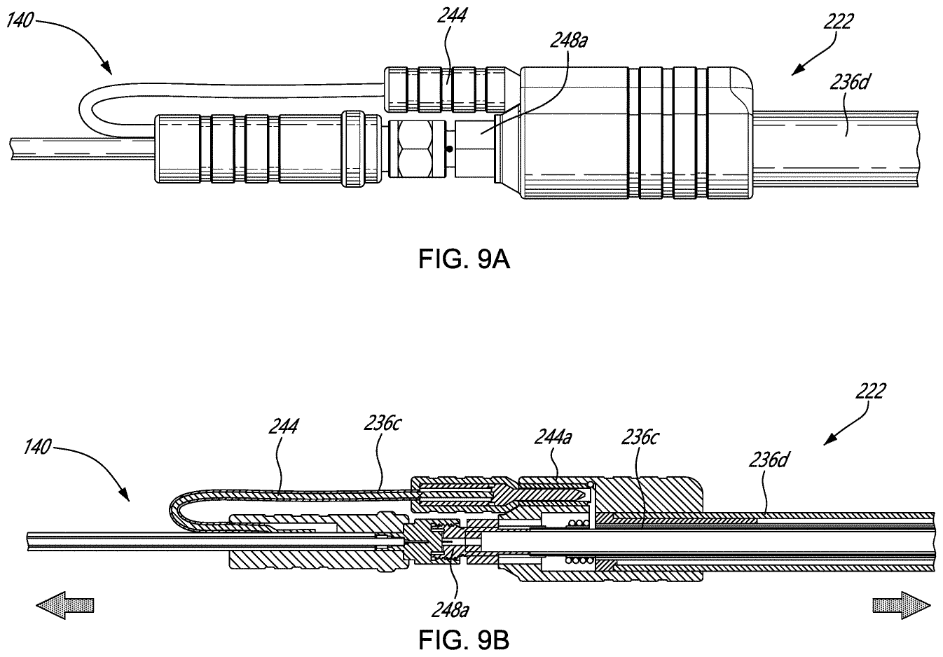

FIGS. 8A and 8B, and FIGS. 9A and 9B, present an example of a cable 222 which can be used to establish 4 independent electrical connections. In this example, the cable 222 has connectors 248a, 248b, 244a, 244b, at both ends. The connectors 248b, 244b at the first end are shown connected to electronics hardware 220 in FIGS. 8A and 8B, and the connectors 248a, 248b at the second end are shown connected to a sensor cable segment 140 in FIGS. 9A and 9B. In this specific embodiment, each end has a conventional co-axial cable connector 248 a, 248b (male and female, respectively, in this embodiment) configured to establish the two first electrical connections 236a, 236b shown in FIG. 5, between the first and second conductors of the cable 222 and the two outputs of the electronic hardware 220. Moreover, each end has a pin connector 244a, 244b (female and male, respectively, in this embodiment) electrically connected, via a wire, to the third conductor 236c. The pin connectors 244a, 244b can be used to conveniently establish the distinct return electrical connection of the third conductor 236c with the back plane and the electronic ground 246. Accordingly, establishing the first three electrical connections can be made as easy as establishing a coaxial connection and a pin connection.

There are various ways of establishing the fourth electrical connection, between the fourth conductor 236d and the machine ground 128c. In some cases, it may be found suitable to simply allow the external surface of the cable, offered by the fourth conductor 236d, to fall loosely into contact with a grounded metallic component or directly with the ground under the action of gravity. In the illustrated embodiment, it was optionally preferred to control this connection using a dedicated bracket 250 made of an electrically conductive material, which can be secured to a grounded metallic component or directly to the ground via a suitable fastener, and which can be configured in a manner to snappingly receive the cable 222 in a manner to establish a firm electrical contact between the exposed fourth conductor 236d and the ground across the electrically conductive body of the bracket 250 which is in electrical contact with both.

Comparing FIGS. 8A and 8B with FIGS. 9A and 9B shows how it can be convenient to use a same type of connector at both ends. However, it will be understood that many other connector configurations are possible.

As can be understood, the examples described above and illustrated are intended to be exemplary only. For instance, in the illustrated embodiment, a male connector of the cable is used to establish the electrical connections with the electronic hardware, and a female connector of the cable is used to establish the electrical connections with the sensor, but the opposite may be preferred in some alternate embodiments. The scope is indicated by the appended claims.

What is claimed is:

1. An air gap monitoring system comprising:
electronic hardware including a high frequency signal generator having a first output, a second output and a return;
a capacitive sensor having a sensing body secured to an internal surface of a stator of a rotary electric machine and facing a rotor of the rotary electric machine, the sensing body having a first sensor conductor, a second sensor conductor and a third sensor conductor;
a cable connected between the electronic hardware and the capacitive sensor, the cable having a first cable conductor establishing a first electrical connection between the first output and the first sensor conductor, a second cable conductor establishing a second electrical connection between the second output and the second sensor conductor, a third cable conductor establishing a third electrical connection between the return and the third sensor conductor, and a fourth cable conductor connected to one or more ground reference, the first electrical connection, second electrical connection, third electrical connection and fourth electrical connection being electrically insulated from one another.

2. The air gap monitoring system of claim 1 wherein the electronic hardware includes an electronic ground reference of the high frequency signal generator, the electronic ground reference connected to the return.

3. The air gap monitoring system of claim 1 wherein the cable is a quadriaxial cable having a central conductor, a second conductor surrounding the central conductor and insulated from the central conductor by a first insulator, a third conductor surrounding the second conductor and insulated from the second conductor by a second insulator, and a fourth conductor surrounding the third conductor and insulated from the third conductor by a third insulator.

4. The air gap monitoring system of claim 3 wherein the central conductor, first insulator, second conductor, second insulator, third conductor and third insulator form part of a triaxial cable, and wherein the fourth conductor is provided in the form of an interlock type flexible metallic conduit.

5. The air gap monitoring system of claim 1 wherein the cable has coaxial connectors connecting the first conductor and second conductor at two opposite ends, the sensor has a triaxial cable segment having a sensor coaxial connector, and the electronic hardware has a hardware coaxial connector.

6. The air gap monitoring system of claim 5 wherein the cable further has pin connectors connecting the third conductor at the two opposite ends, the triaxial cable having a sensor pin connector, and the electronic hardware having a hardware pin connector.

7. The air gap monitoring system of claim 1 wherein the fourth conductor is exposed. 8. The air gap monitoring system of any one of claims 1 to 7 wherein the cable forms part of a series of two or more cables connected to one another in series, the series of two or more cables having a length greater than 15 m.

9. The air gap monitoring system of claim 1 wherein the first sensor conductor has a sensing surface, the second sensor conductor has a mask, and the third sensor conductor has a background, the sensing surface, mask and background being separated from one another by electrical insulators, the sensing body being affixed to the internal surface of the stator via the background.

10. The air gap monitoring system of claim 1 wherein the cable further has a male connector at a first one of the two opposite ends, and a female connector at a second one of the two opposite ends, wherein the male connector has a male coaxial connection element, and a male pin connector element, and the female connector has a female coaxial connection element, and a female pin connector element.

11. The air gap monitoring system of claim 1 wherein the fourth cable conductor is engaged in mechanical and electrical contact with a bracket having a body made of electrically conductive material, the bracket being grounded.

12. A method of monitoring an air gap of a rotary electric machine having a stator and a rotor using a capacitive sensor, the capacitive sensor having a background secured to an internal surface of the stator, a sensing surface facing the rotor, and a mask between the internal surface and the background, the method comprising, during operation of the rotary electric machine:
communicating a first high frequency signal to the sensing surface via a first electrical conductor of a cable;
communicating a second high frequency signal to the mask via a second electrical conductor of the cable;
communicating a return signal from the background via a third electrical conductor of the cable; and
establishing a ground reference of the rotary electric machine in a fourth electrical conductor of the cable;
while maintaining the first, second, third and fourth electrical conductors electrically insulated from one another.

13. A cable having a length extending between two opposite ends, the cable comprising first conductor extending along the length and externally connectable at each one of the two opposite ends, a first insulator surrounding the first conductor, a second conductor surrounding the first insulator and externally connectable at each one of the two opposite ends, a second insulator surrounding the second conductor, a third conductor surrounding the second insulator and externally connectable at each one of the opposite ends, a third insulator surrounding the third conductor, and a fourth conductor surrounding the third insulator.

14. The cable of claim 13 wherein the central conductor, first insulator, second conductor, second insulator, third conductor and third insulator form part of a triaxial cable.

15. The cable of claim 13 wherein the cable has coaxial connectors connecting the first conductor and second conductor at two opposite ends.

16. The cable of claim 15 wherein the cable further has pin connectors connecting the third conductor at the two opposite ends.

17. The cable of claim 13 wherein the fourth conductor is exposed.

18. The cable of claim 13 wherein the fourth conductor embodied as a metal arranged in a flexible interlock configuration.

19. The cable of claim 18 provided in combination with a bracket, the bracket having a metallic body having a fastener aperture operable to connect the bracket to a machine ground, and a holder operable to snappingly receive the fourth conductor.
